(19) United States
(12) Patent Application Publication
(10) Pub. No.: US 2010/0019380 A1
(43) Pub. Date: Jan. 28, 2010

(54) INTEGRATED CIRCUIT WITH MICRO-PORES CERAMIC HEAT SINK

(76) Inventors: Yi Min Lin, Taipei County (TW); Ta-Chi Hung, Taipei City (TW)

Correspondence Address: Muncy, Geissler, Olds & Lowe, PLLC, P.O. BOX 1364, FAIRFAX, VA, 22038-1364, US

(21) Appl. No.: 12/508,227

(22) Filed: Jul. 23, 2009

(30) Foreign Application Priority Data
Jul. 24, 2008 (TW) 097213231

(51) Int. Cl. H01L 23/34; H05K 7/20

(52) U.S. Cl. 257/720; 361/718; 361/697; 257/E23.08

(57) ABSTRACT

An integrated circuit includes an integrated circuit device, a micro-pores ceramic heat sink and a heat conductive medium. The micro-pores ceramic heat sink is placed on a surface of the integrated circuit device. The heat conductive medium is placed in between the integrated circuit device and the micro-pores ceramic heat sink with one surface joined to the integrated circuit device and the other surface to the micro-pores ceramic heat sink.

### BACKGROUND OF INVENTION

1. Field of Invention

This invention relates to an integrated circuit using a micro-pores ceramic heat sink and more particularly to an integrated circuit having a micro-pores ceramic heat sink that can evenly dissipate the heat generated by an integrated circuit device toward surfaces of the micro-pores ceramics heat sink and therefore reduce the heat resistance and enhance the heat dissipation effect.

2. Related Prior Art

A conventional heat sink for an integrated circuit device includes at least one metallic heat dissipating fin set and a cooling fan mounted on the metallic heat dissipating fin set. The metallic heat dissipating fin set is mounted on one side of the integrated circuit device via heat conductive adhesive. In this way, while the integrated circuit device operates and generates heat, the cooling fan guides airflow to the metallic heat dissipating fin set for heat dissipation.

Although the prior heat sink can help to dissipate the heat generated by the integrated circuit device; however, since the heat conductive adhesive is the only heat conductive medium which serves to join the integrated circuit device and the metallic heat dissipating fin set together. Accordingly, when the metallic heat dissipating fin set is about to absorb the heat generated by the integrated circuit device, the heat resistance is quite high, which causes the heat not being able to be evenly dispersed to the metallic heat dissipating fin set. The heat dissipation effect is limited. The accumulated heat may cause a decrease in performance of the integrated circuit device or damage to the integrated circuit device.

Another type of heat sink for an integrated circuit device is a micro-pores ceramics heat sink, as disclosed in Chaby Hsu U.S. Pat. No. 6,967,844. The micro-pores ceramics heat sink includes a thermal conductive layer, a heat dissipation layer and a cooling fan. The thermal conductive layer is provided to be mounted on a surface of a heat source to absorb heat from the heat source. The heat dissipation layer combines with the thermal conductive layer and has a micro-pores structure with hollow crystals to provide a relatively greater surface area. The cooling fan mounted on the heat dissipation layer to provide a forced convection effect.

### SUMMARY OF INVENTION

Broadly stated the present invention is directed to an integrated circuit using a micro-pores ceramic heat sink along with a heat conductive medium for heat dissipation. The integrated circuit mainly includes an integrated circuit device, a micro-pores ceramic heat sink and a heat conductive medium. The micro-pores ceramic heat sink is disposed on a top surface of the integrated circuit device. The heat conductive medium is placed in between the integrated circuit device and the micro-pores ceramic heat sink with one surface joined to the integrated circuit device and the other surface joined to the micro-pores ceramic heat sink. In such a fashion, heat generated by the integrated circuit device would be evenly dispersed to relatively greater surfaces of the micro-pores ceramic heat sink, and thereby the resistance can be reduced and the heat dissipation effect is enhanced.

The present invention and the advantages thereof will become more apparent upon consideration of the following detailed description when taken in conjunction with the accompanying drawings.

### BRIEF DESCRIPTION OF DRAWINGS

The invention is illustrated by the accompanying drawings in which corresponding parts are identified by the same numerals and in which:

FIG. 1 is a perspective view of an integrated circuit in accordance with a first embodiment of the invention;

FIG. 2 is an exploded view of the integrated circuit of FIG. 1;

FIG. 3 is a perspective view of an integrated circuit in accordance with a second embodiment of the invention;

FIG. 4 is a perspective view of an integrated circuit in accordance with a third embodiment of the invention;

### DETAILED DESCRIPTION OF EMBODIMENTS

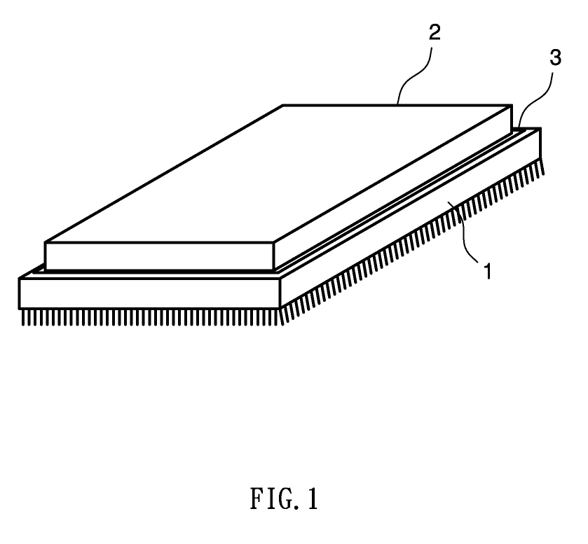

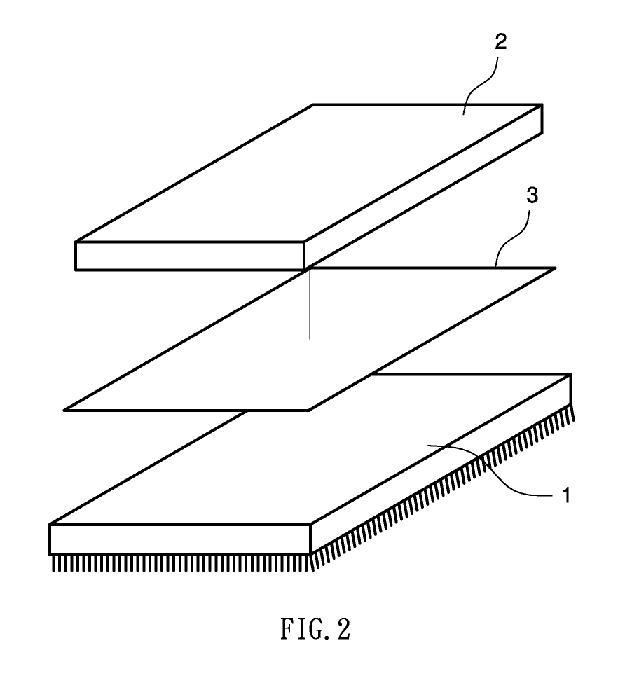

Turning in detail to the drawings, an integrated circuit according to a first embodiment of the invention is illustrated in FIGS. 1 and 2. The integrated circuit comprises an integrated circuit device 1, a micro-pores ceramic heat sink 2 and a heat conductive medium 3.

The integrated circuit device 1 may be a bare die or a packaged chip. The micro-pores ceramic heat sink 2 is placed on top of the integrated circuit device 1. The heat conductive medium 3 is placed in between the integrated circuit device 1 and the micro-pores ceramic heat sink 2 with one surface joined to the integrated circuit device 1 and the other surface joined to the micro-pores ceramic heat sink 2.

The heat conductive medium 3 may be a thermally conductive tape, such as an aluminum foil tape, a silicone sheet or a fiberglass sheet, with adhesive on both sides and a thickness in a range of 0.1 mm to 0.25 mm.

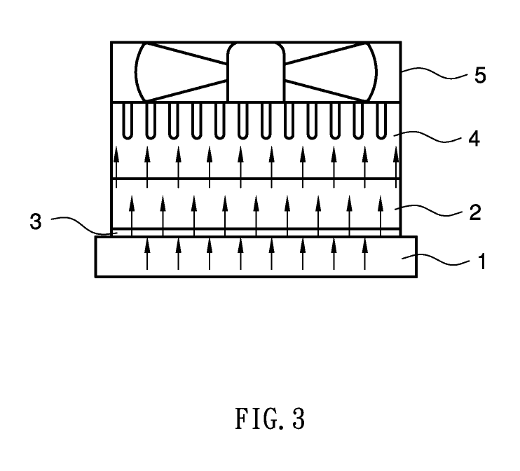

FIG. 3 provides a cross-sectional view of an integrated circuit in a second embodiment. As with the integrated circuit of FIG. 1, the integrated circuit of FIG. 3 further includes a heat dissipating fin set 4 and a cooling fan 5. The heat dissipating fin set 4 is disposed on top of the micro-pores ceramic heat sink 2. The cooling fan 5 is mounted on top of the heat dissipating fin set 4. Since the cooling fan 5 provides a forced convection effect, the micro-pores ceramic heat sink 2 along with the cooling fan 5 performs relative excellent heat dissipation effect. It is noted that the micro-pores ceramic heat sink 2 and the heat dissipating fin set 4 may be separately formed and mounted together. Alternatively, the micro-pores ceramic heat sink 2 and the heat dissipating fin set 4 may be formed in one piece with the same material via a molding process.

While the integrated circuit device 1 operates and generates heat, the heat conductive medium 3 evenly transfers the heat to the surfaces of the micro-pores ceramic heat sink 2. In this time, the heat resistance is reduced and the heat conductivity is enhanced. Afterward, the heat dissipating fin set 4 absorbs the heat from the micro-pores ceramic heat sink 2 and the cooling fan 5 guides airflow into the heat dissipating fin set 4 to disperse the heat. In this way, the present invention utilizes the characteristic of the micro-pores ceramic heat sink 2 with the help of the heat conductive medium 3, the heat dissipating fin set 4 and the cooling fan 5 to perform an excellent heat dissipation effect.

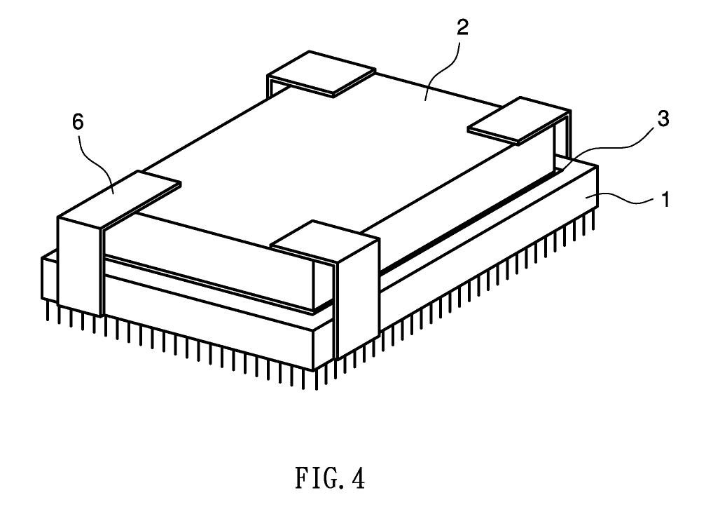

FIG. 4 provides a perspective view of an integrated circuit in a third embodiment. As with the integrated circuit of FIG. 1, the integrated circuit of FIG. 4 further includes a plurality of fasteners 6 at corners thereof to secure the integrated circuit device 1 and the micro-pores ceramic heat sink 2 together. In this way, the bonding between integrated circuit device 1 and the micro-pores ceramic heat sink 2 are strengthened, and thereby enhances the heat dissipation effect.

It will be appreciated that although a particular embodiment of the invention has been shown and described, modifications may be made. It is intended in the claims to cover such modifications which come within the spirit and scope of the invention.

The invention claimed is:

1. An integrated circuit, comprising:
an integrated circuit device;
a micro-pores ceramic heat sink placed on a surface of the integrated circuit device; and
a heat conductive medium placed in between the integrated circuit device and the micro-pores ceramic heat sink with one surface joined to the integrated circuit device and the other surface joined to the micro-pores ceramic heat sink.

2. The integrated circuit of claim 1, wherein the heat conductive medium is a thermally conductive aluminum foil tape with adhesive on both sides and has a thickness in a range of 0.1 mm to 0.25 mm.

3. The integrated circuit of claim 1, wherein the heat conductive medium is a thermally conductive silicone sheet with adhesive on both sides and has a thickness in a range of 0.1 mm to 0.25 mm.

4. The integrated circuit of claim 1, wherein the heat conductive medium is a thermally conductive fiberglass sheet with adhesive on both sides and has a thickness in a range of 0.1 mm to 0.25 mm.

5. The integrated circuit of claim 1, further comprising a heat dissipating fin set mounted on the micro-pores ceramic heat sink.

6. The integrated circuit of claim 5, further comprising a cooling fan mounted on the heat dissipating fin set.
